(19) United States
(12) Patent Application Publication
(10) Pub. No.: US 2010/0103611 A1
(43) Pub. Date: Apr. 29, 2010

(54) ELECTRONIC DEVICE

(75) Inventors: Ching-Fu Yang, Taipei City (TW); You-Chi Liu, Taipei City (TW); Kuo-Nan Ling, Taipei City (TW); Po-An Lin, Taipei City (TW); Yung-Hui Chen, Taipei City (TW); Hao-Ying Chang, Taipei City (TW); Jui-Tsen Huang, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: COMPAL ELECTRONICS, INC., Taipei City (TW)

(21) Appl. No.: 12/534,859

(22) Filed: Aug. 4, 2009

Related U.S. Application Data
(60) Provisional application No. 61/108,028, filed on Oct. 24, 2008.

(51) Int. Cl. H05K 7/00

(52) U.S. Cl. 361/679.55

(57) ABSTRACT

An electronic device having a touching function, including a touching region, a housing, a touch module, and a switch module is provided. The touching region is performing the touching function. The touching region is located over the housing. The touch module is disposed in the housing in correspondence with the touching region. The switch module includes at least one switch and is disposed under the touch module. The touch module is bent under force to turn on the switch when the touching region is touched.

### CROSS-REFERENCE TO RELATED APPLICATION

This application claims the priority benefit of U.S. provisional application Ser. No. 61/108,028, filed Oct. 24, 2008. The entirety of the above-mentioned patent application is hereby incorporated by reference herein and made a part of specification.

### BACKGROUND OF THE INVENTION

1. Field of the Invention

The present invention relates to electronic devices, and more particularly, to an electronic device with a touching region.

2. Description of Related Art

FIG. 1 A illustrates a conventional electronic device. Referring to FIG. 1A, the conventional electronic device 100 is a notebook computer. In order to effectively reduce the overall size of the electronic device 100 for ease of carry, peripheral devices such as the mouse have been integrated into a main unit of the electronic device 100. FIG. 1B is a partial view of the electronic device of FIG. 1A. Referring to FIGS. 1A and 1B, the conventional electronic device 100 includes a housing 110 with a touch panel opening 112 and two function key openings 114. A touch panel 120 is disposed in the touch panel opening 112, and two interconnected keys 130 are disposed in the function key openings 114, respectively. A frame 140 is disposed below the housing 110 with the touch panel 120 and the keys 130 being positioned between the frame 140 and the housing 110. In addition, a switch circuit board 150 disposed under the frame 140 includes two push switches 152 disposed in correspondence with the keys 130.

Typically, a spring 160 needs to be disposed under the key 130 in order to enable the key 130 to return to its original position after the key 130 is forced to touch a selected push switch 152. Specifically, the key 130 is returned to its original position under the influence of the spring restoring force of the spring 160 after the force exerted on the key 130 is removed.

### SUMMARY OF THE INVENTION

Accordingly, the present invention is directed to an electronic device in which the usable area of the touch module can be increased.

The present invention provides an electronic device having a touching function. The electronic device includes a touching region, a housing, a touch module, and a switch module. The touching region for being touched to translate the motion and the position and performing the touching function is located over the housing. The touch module is disposed in the housing in correspondence with the touching region. The touch module comprises at least one connecting portion through which the touch module is connected to the housing, wherein the touch module is bent by pressing the touching region. The switch module comprises at least one switch and is disposed under the touch module. The switch module is turned on when the bent touch module presses the switch module by pressing the touching region.

According to one embodiment of the present invention, the touch module comprises a touch panel and the connecting portion extends horizontally from the touch panel.

According to one embodiment of the present invention, the touch module comprises a touch panel and a supporting frame, the supporting frame is disposed adjacent the touch panel, and the connecting portion extends horizontally from the supporting frame.

According to one embodiment of the present invention, the supporting frame comprises a first frame and a second frame, the touch panel is disposed between the first frame and the second frame, and the connecting portion extends horizontally from the first frame or the second frame.

According to one embodiment of the present invention, the touching region is an opening of the housing.

According to one embodiment of the present invention, the touching region is a flexible shell.

According to one embodiment of the present invention, the switch is a mechanical switch or a membrane switch.

According to one embodiment of the present invention, the switch module comprises two switches, and the touch module comprises a spacer located between the two switches.

According to one embodiment of the present invention, the touch module comprises a limiting element which interferes with the housing to limit a movement of the touch module.

According to one embodiment of the present invention, the touch module comprises a pressing member positioned in correspondence with the switch.

According to one embodiment of the present invention, the connecting portion is disposed at one side of the touch module, and the switch of the switch module is disposed under an opposite side of the touch module relative to the connecting portion.

According to one embodiment of the present invention, the connecting portion comprises a flexible section, the flexible section comprises a connecting end at a distal end thereof, and each connecting portion is connected to the housing through the connecting end.

According to one embodiment of the present invention, the connecting portion comprises two flexible sections, a connecting end is formed at a junction of the two flexible sections, and each connecting portion is connected to the housing through the connecting end.

In view of the foregoing, the switch module of the electronic device of the present invention is disposed under the touch module. When the user directly presses the touch module through the touching region of the housing, or presses the touching region to indirectly press the touch module at a position corresponding to the switch of the switch module, the touch module is bent under the pressing force to turn on the switch. When compared to the related art, the function key region can be eliminated in the present invention, such that the area of the touching region can be increased without increasing the overall size of the housing. In addition, in the electronic device of the present invention, the touch module is bent under the pressing force can be returned to its original position under the influence of the spring storing force of the touch panel or the supporting frame, thereby eliminating the spring as used in the related art. Therefore, by eliminating the function keys and spring, not only is the component cost reduced, but also the present invention can be adapted for electronic devices with limited spaces in its housing.

In order to make the aforementioned and other features and advantages of the present invention more comprehensible, embodiments accompanied with figures are described in detail below.

### BRIEF DESCRIPTION OF THE DRAWINGS

FIG. 1A illustrates a conventional electronic device.

FIG. 1B is a partial view of the electronic device of FIG. 1A.

FIG. 2 illustrates an electronic device according to a first embodiment of the present invention.

FIG. 3A illustrates the touch module and the switch module of the first embodiment.

FIG. 3B and FIG. 3C are views showing the electronic device of the first embodiment being used by a user.

FIG. 3D and FIG. 3E are other views showing the electronic device of the first embodiment being used by a user.

FIG. 4A illustrates an electronic device according to a second embodiment of the present invention.

FIG. 4B is an assembled, bottom view of the electronic device of the second embodiment.

FIG. 5A illustrates an electronic device according to a, third embodiment of the present invention.

FIG. 5B is another view illustrating the electronic device of the third embodiment.

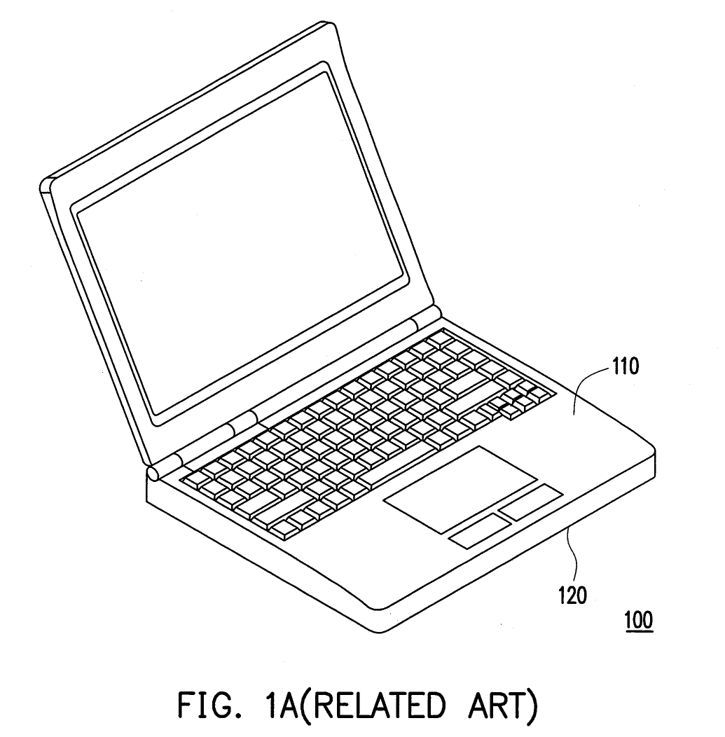

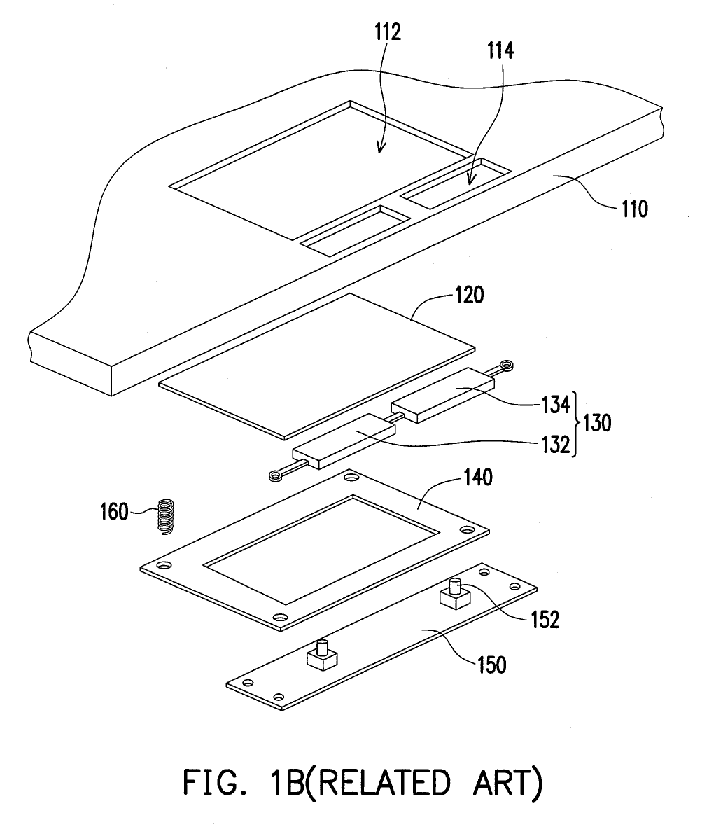

### DESCRIPTION OF THE EMBODIMENTS

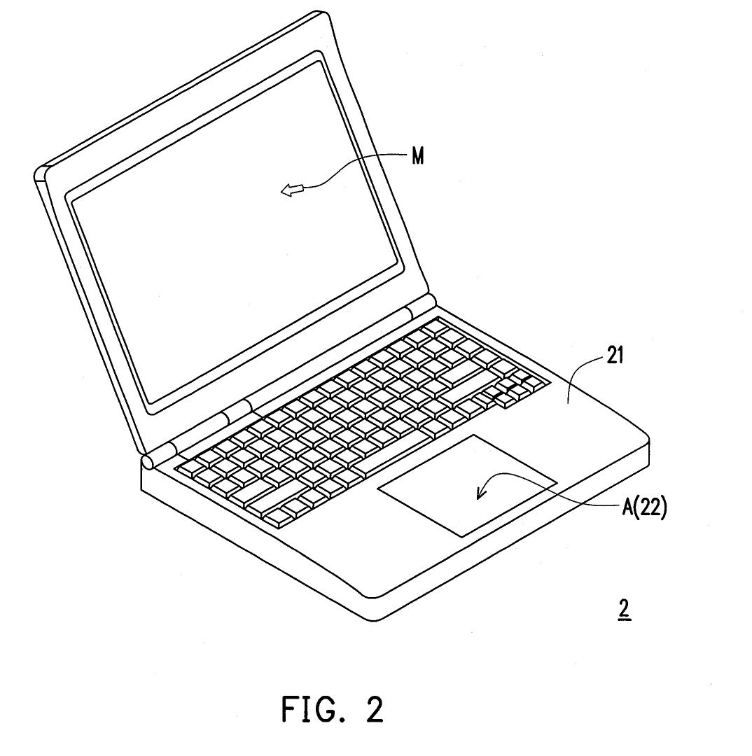

Referring to FIGS. 2 to 5B, an electronic device 2 having a touching function according to a first embodiment of the present invention is shown. The electronic device 2 includes a touching region A, a housing 21, a touch module 22, and a switch module 23.

Referring to FIG. 2, touching region A used for being touched to translate the motion and the position and performing the touching function is located over the housing 21. The touch module 22 is disposed in the housing 21 in correspondence with the touching region A. In the present embodiment, the touching region A is an opening of the housing 21. The touch module 22 is exposed outside of the housing 21 via the touching region A, such that a user's finger can move on the touch module 22 through the touching region A to thereby change the location of the cursor M displayed on the electronic device 2.

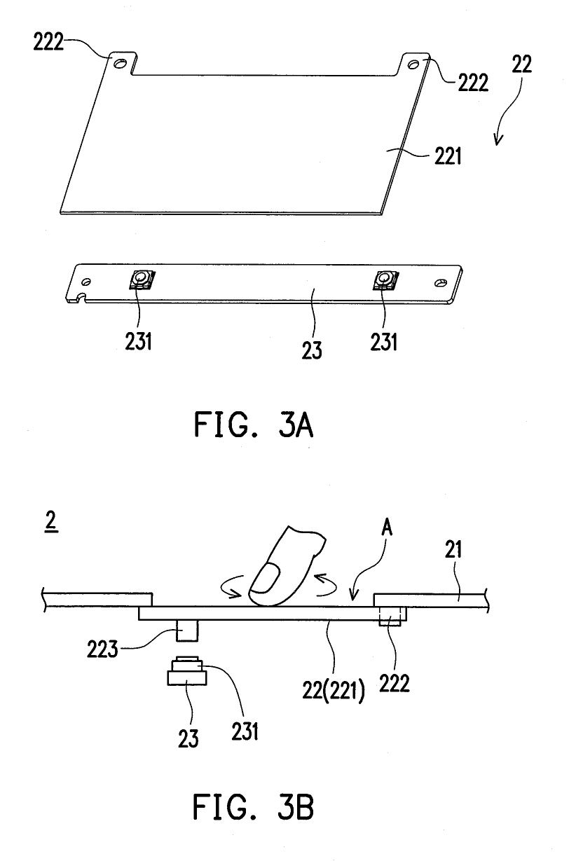

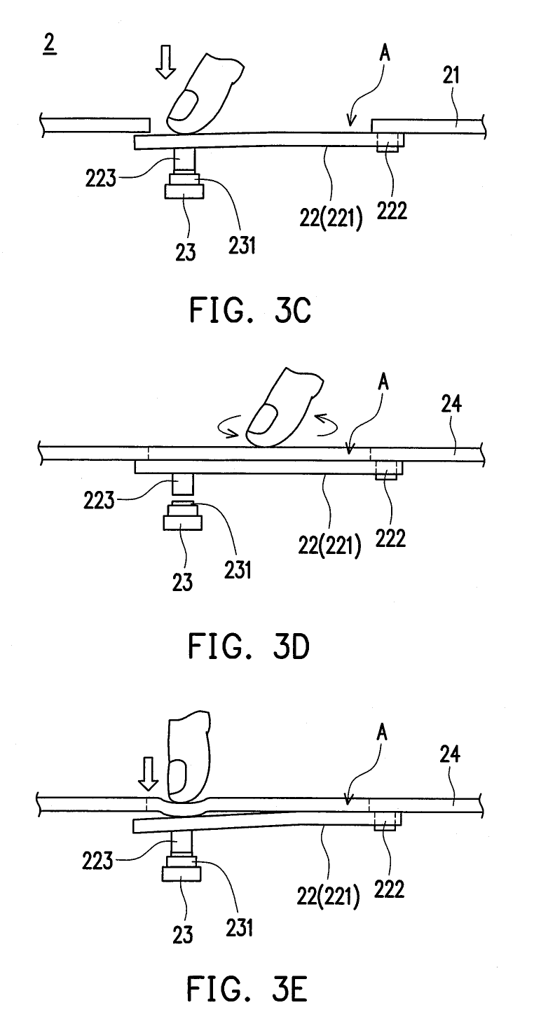

Referring to FIG. 3A, the touch module 22 includes at least one connecting portion 222 through which the touch module 22 is connected to the housing 21, wherein the touch module 22 is bent by pressing the touching region A. In the present embodiment, the touch module 22 includes a touch panel 221, and the connecting portion 222 extends horizontally from a side of the touch panel 221. Referring to FIG. 3B, the connecting portion 222 can be connected to the housing 21 through soldering, fastening, or a rabbet joint. The touch module 22 further includes two pressing members 223 protruding from a backside of the touch panel 221. The material of each pressing member 223 may be rubber, plastic, or metal. Referring to FIG. 3C, the touch panel 221 is a printed circuit board (PCB), due to the flexibility of the material of the PCB, the touch module 22 is bent under force when the user presses the touch module 22 through the touching region A, and is returned to its original position under the influence of its own elasticity of the touch panel 221 when the pressing force exerted by the user is removed.

The switch module 23 is disposed under the touch module 22 and includes at least one switch 231. In the present embodiment, two switches 231 are illustrated. It should be understood that the number of the switches 231 of the switch module 23 can change according to actual requirements. In the present embodiment, the switches 231 are disposed under an opposite side of the touch module 22 relative to the connecting portions 222 of the touch module 22. Because the pressing members 223 of the touch module 22 are disposed in positional correspondence with the switches 231 of the switch module 23, respectively, when the touch module 22 is bent under force, the pressing member 223 is moved downward to turn on the corresponding switch 231. As such, the switches 231 can be turned on respectively to execute the selecting or confirming function as achieved by the two conventional function keys. It should be understood that the switches 231 can cooperate with software to execute embedded predetermined function or user-defined function.

In addition, while the switch 231 is illustrated as a mechanical switch in the present embodiment, the switch 231 can also be a membrane switch (not shown). The membrane, switch generally includes a circuit substrate and a flexible conductive tab. The circuit board includes at least one electrical node, and the flexible conductive tab can be attached to one side of the touch module and includes at least one electrical contact. As such, when the electrical contact is brought into contact with the electrical node, the same function can be achieved as the mechanical switch.

Referring again to FIG. 3B, when the user's finger moves in the touching region A of the housing 21, the touch module 22 can sense the movement of the finger and change the location of the cursor displayed on the electronic device 2 accordingly. Referring to FIG. 3C, when the user presses the location within the touching region A that corresponds to one of the switches 231 of the switch module 23, the touch module 22 is bent under force to thereby turn on the corresponding switch 231. When the pressing force exerted by the user's finger is removed, the touch module 22 is returned to its original position (as shown in FIG. 3B) under the influence of the elasticity of the touch panel 221, such that the corresponding switch 231 is not turned on.

It is noted, however, that the touching region of the housing may be a structure other than the opening. Referring to FIG. 3D, the touching region A of the housing 24 is a flexible shell. When the user's finger moves in the touching region A of the housing 24, the touch module 22 can likewise sense the movement of the user's finger and change the location of the cursor M displayed on the electronic device 2 correspondingly. Referring to FIG. 3E, due to the flexibility of the material of the touching region A, when the user's finger presses the touching region A, the touching region A is deformed under the pressing force such that the user's pressing force indirectly causes the touch module 22 bending under the touching region A, thereby turning on the switch 231 of the switch module 23. Therefore, no matter whether the touching region A of the housing 21 is the opening or the flexible shell, the touch module 22 can sense the movement of the user's finger and the user can directly or indirectly press the touching region A of the housing 21, 24, such that the touch module 22 is bent under the pressing force to thereby turn on the switch 231 of the switch module 23.

It is noted, however, that the connecting portion 222 of the touch module 22 can be formed in another suitable manner in addition to being formed by horizontally extending the touch panel 221.

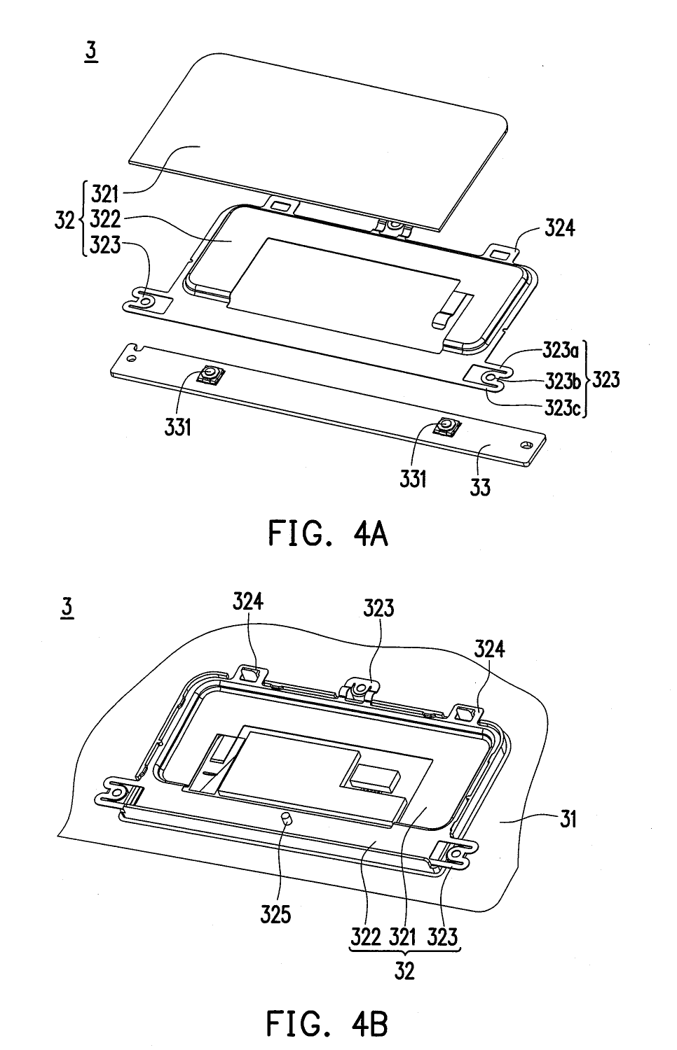

Referring to FIGS. 4A and 4B, an electronic device 3 according to a second embodiment of the present invention is shown. The electronic device 3 includes a housing 31, a touch module 32, and a switch module 33. The touch module 32 includes a touch panel 321 and a supporting frame 322. The supporting frame 322 is disposed adjacent the touch panel 321. Three connecting portions 323 extend from three sides of the supporting frame 321, respectively. Each connecting portion 323 has two flexible sections 323a and a connecting end 323b formed at a junction of the two flexible sections 323a. As such, the connecting end 323b of each connecting portion 323 can be connected to the housing 31 through soldering or fastening, and the elasticity of the flexible sections 323a of each connecting portion 323 can return the touch module 32 bent under force to its original position.

In addition, the touch module of the present embodiment further includes two limiting elements 324 and a spacer 325. Each limiting element 324 extends from one side of the supporting frame 322 and can be mounted with the housing 31 through fastening, heat-melting, socket connection, rabbet joint or other suitable connection means. Each limiting element 324 interferes with the housing 31 to limit the movement of the touch module 32. With the provision of each limiting element 324, when the touch module 32 is bent under the pressing force, an unduly large gap between the touch module 32 and the housing 31 and hence an appearance defect can be avoided. In addition, the spacer 325 protrudes from a backside of the touch module 32 and is positioned between the two switches 331 of the switch module 33. The material of the spacer 325 may be rubber, plastic or metal. It is noted that the spacer 325 may be integrally formed with the supporting frame 322. When it is desired to turn on one of the switches 331 of the switch module 33, the spacer 325 can support the touch module 32 to prevent the bent touch module 32 from mistakenly touching the other switch 331 of the switch module 33.

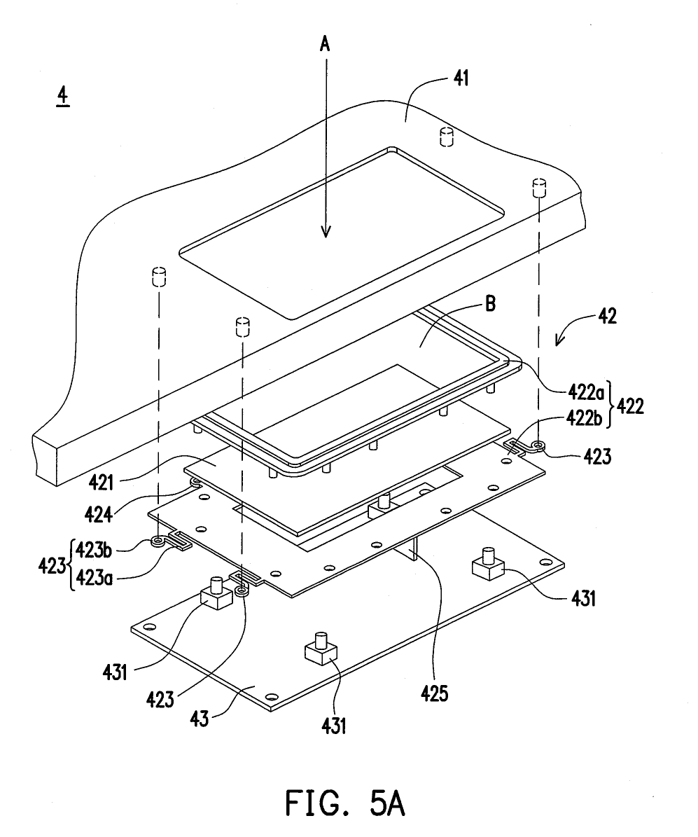

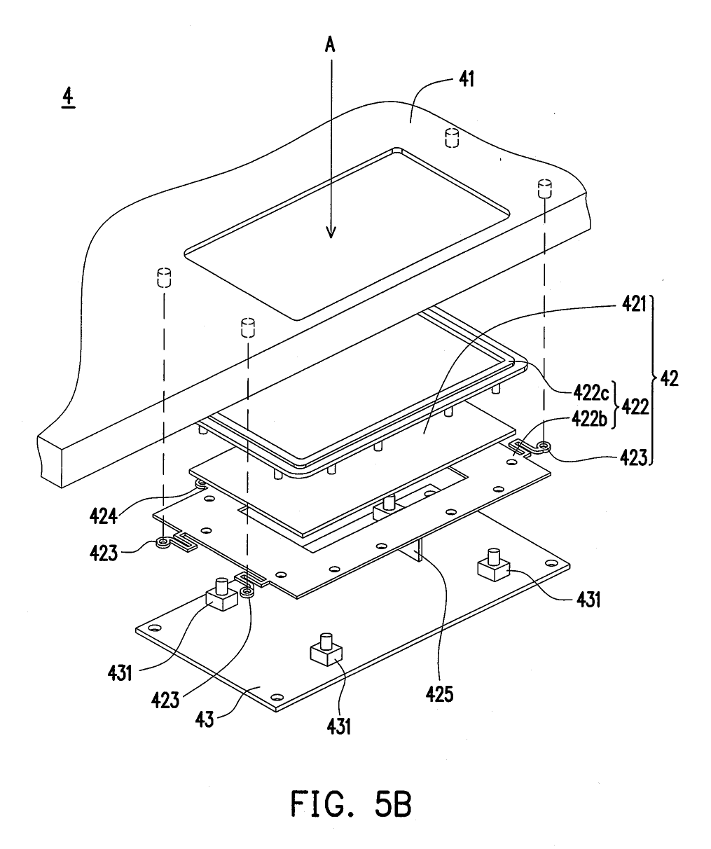

Referring to FIG. 5A, an electronic device 4 according to a third embodiment of the present invention is shown. The electronic device 4 includes a housing 41, a touch module 42, and a switch module 43. In the present invention, the touching region A of the housing 41 is an opening. The touch module 42 includes a touch panel 421 and a supporting frame 422. The supporting frame 422 is formed by assembling a first frame 422a and a second frame 422b. The touch panel 421 is disposed between the first frame 422a and the second frame 422b. In addition, fourth connecting portions 423 of the touch module 42 extend horizontally from the first frame 422a or the second frame 422b and are connected to the housing 41.

Further, the switch module 43 of the present embodiment has four switches 431. The connecting portions 423 of the touch module 42 are arranged with two disposed on one side of the second frame 422b and the other two disposed on an opposite side of the second frame 422b. In addition, each connecting portion 423 includes a generally S-shaped flexible section 423a. Each flexible section 423a includes a connecting end 423b at a distal end of the flexible section 423a. A through hole is defined in the connecting end 423b and can fit over a portion of the housing 41. Therefore, the user can press the touch module 42 at a position corresponding to a selected switch 431 such that the touch module 42 is bent to turn on the selected switch 431 to execute the predetermined function.

In the present embodiment, the first frame 422a may have an opening B such that the touch panel 421 can be exposed through the opening B and the touching region A. Alternatively, as shown in FIG. 5B, the first frame 422c may also be a decorative cover which hides the touch panel 421 within the housing 41.

In addition, the touch module 42 of the present embodiment further includes two limiting element 424 and a spacer 425. The structure and function of the limiting element 424 and the spacer 425 are the same as those of the limiter 324 and spacer 325 in the second embodiment, and are therefore not repeated herein.

It is noted that the foregoing embodiments are only illustrative and it will be appreciated by those skilled in the art that the embodiments described herein can be combined or elements thereof can be replaced without departing the spirit of the present invention.

In summary, the switch module of the electronic device of the present invention is disposed under the touch module. When the user directly presses the touch module through the touching region of the housing, or presses the touching region to indirectly press the touch module at a position corresponding to the switch of the switch module, the touch module is bent under the pressing force to turn on the switch. When compared to the prior art, the function key region can be eliminated in the present invention, such that the area of the touching region can be increased without increasing the overall size of the housing. In addition, in the electronic device of the present invention, the touch module bent under the pressing force can be returned to its original position under the influence of the elasticity of the touch panel or the supporting frame, thereby eliminating the spring as used in the prior art. Therefore, by eliminating the function keys and the spring, not only is the component cost reduced, but also the present invention can be adapted for electronic devices with limited spaces in its housing.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic device having a touching function, comprising:
a touching region for being touched to translate the motion and the position an performing the touching function;
a housing wherein the touching region is located over the housing;
a touch module disposed in the housing in correspondence with the touching region, the touch module comprising at least one connecting portion through which the touch module is connected to the housing, wherein the touch module is bent by pressing the touching region; and
a switch module comprising at least one switch and disposed under the touch module, wherein the switch module is turned on when the bent touch module presses the switch module by pressing the touching region.

2. The electronic device according to claim 1, wherein the touch module comprises a touch panel and the connecting portion extends horizontally from the touch panel.

3. The electronic device according to claim 1, wherein the touch module comprises a touch panel and a supporting frame, the supporting frame is disposed adjacent the touch panel, and the connecting portion extends horizontally from the supporting frame.

4. The electronic device according to claim 3, wherein the supporting frame comprises a first frame and a second frame, the touch panel is disposed between the first frame and the second frame, and the connecting portion extends horizontally from the first frame or the second frame.

5. The electronic device according to claim 1, wherein the touching region is an opening of the housing.

6. The electronic device according to claim 1, wherein the touching region is a flexible shell.

7. The electronic device according to claim 1, wherein the switch is a mechanical switch or a membrane switch.

8. =The electronic device according to claim 1, wherein the switch module comprises two switches, the touch module comprises a spacer located between the two switches.

9. The electronic device according to claim 1, wherein the touch module comprises a limiting element which interferes with the housing to limit a movement of the touch module.

10. The electronic device according to claim 1, wherein the touch module comprises a pressing member positioned in correspondence with the switch.

11. The electronic device according to claim 1, wherein the connecting portion is disposed at one side of the touch module, and the switch of the switch module is disposed under an opposite side of the touch module relative to the connecting portion.

12. The electronic device according to claim 1, wherein the connecting portion comprises a flexible section, the flexible section comprises a connecting end at a distal end thereof, and each connecting portion is connected to the housing through the connecting end.

13. The electronic device according to claim 1, wherein the connecting portion comprises two flexible sections, a connecting end is formed at a junction of the two flexible sections, and each connecting portion is connected to the housing through the connecting end.
